(19) United States
(12) Patent Application Publication
(10) Pub. No.: US 2023/0208317 A1
(43) Pub. Date: Jun. 29, 2023

(54) Composant de puissance à filtrage local et convertisseur mettant en ?uvre plusieurs composants de puissance à filtrage local

(71) Applicant: THALES, COURBEVOIE (FR)

(72) Inventors: Eric Ravindranath DUBOIS, CHATOU (FR); Hocine KHERBOUCHI, CHATOU (FR); Jean Paul BERGER, CHATOU (FR); Joel DEVAUTOUR, CHATOU (FR)

(21) Appl. No.: 18/147,615

(22) Filed: Dec. 28, 2022

(30) Foreign Application Priority Data
Dec. 28, 2021 (FR) 2114585

(51) Int. Cl. H02M 7/5387; H01L 23/46; H01L 23/00; H02M 7/00

(52) U.S. Cl. CPC H02M 7/5387; H01L 23/46; H01L 24/48; H02M 7/003; H01L 2224/48091; H01L 2224/48249

(57) ABSTRACT

A component which is configured to switch an electrical signal, the component includes an insulating substrate bearing a semiconductor chip which ensures switching of the signal; a sole plate on which the substrate is secured, the sole plate being configured to discharge heat emitted during switching of the component; a conductive plane positioned between the sole plate and the insulating substrate, the conductive plane being insulated electrically against the sole plate; a specific component with impedance of at least 1 Ohm and/or at least 1 µH, by means of which the conductive plane is connected to a reference voltage.

### CROSS-REFERENCE TO RELATED APPLICATION

This application claims priority to foreign French patent application No. FR 2114585, filed on Dec. 28, 2021, the disclosure of which is incorporated by reference in its entirety.

### FIELD OF THE INVENTION

In power electronics, many static converters have been developed, mainly inverters and rectifiers. More complex equipment is also found, such as switch-mode power supplies. These converters are equipped with electronic components which make it possible to switch an electrical signal. The switching components are often known as: “electronic switches”. Amongst these components, diodes, transistors, thyristors, and triacs etc. can be cited.

### BACKGROUND

Power diodes started to be developed in the 1950s. In the 1960s, thyristors and power transistors appeared. Later, in the 1980s, insulated gate bipolar transistors known by the acronym IGBT appeared. This type of transistor combines the advantage of control by means of a field effect transistor, and the low losses by conduction of a bipolar transistor. Hitherto, IGBTs have made it possible to switch power levels of approximately 10 MW to speeds higher than 10 kHz. For lower power levels, transistors of the MOSFET type are also extensively used. In the 2000s, components, and in particular MOSFET transistors appeared, based on silicon carbide (SiC). They make it possible to achieve speeds greater than 1 MHz. More recently, gallium nitride GaN has also been introduced into MOSFET transistors in order to provide electronic switches. Gallium nitride makes it possible to increase the switching speed even more to frequencies greater than 10 MHz.

By switching electrical power signals, these components generate thermal losses which must be discharged. The electronic switches are mostly cooled by means of radiators making it possible to discharge the heat by convection of air circulating along walls of the radiator. The radiators can also be equipped with channels in which a cooling fluid circulates.

In order to ensure good thermal transfer of the component to its radiator, it is necessary to reduce as far as possible the thermal resistance of the path travelled by the heat from its area of emission in the core of the component as far as the radiator which permits dissipation of this heat. The electronic switch mostly has a metal sole plate which is positioned in the immediate vicinity of the core of the component, and via which the heat to be discharged passes. The sole plate can be insulated electrically against the component, or can form one of its connection points. During the fitting of the electronic switch, the sole plate is placed against the radiator. The contact of the sole plate on the radiator can be thermally improved by means of a thermally conductive paste. It is also possible to interpose an electrical insulator between the sole plate and the radiator in the form of a small plate based on aluminium oxide, mica or silicon.

The safety of users of equipment which uses electronic switches generally requires earthing of the radiators. For better dissipation of the heat, it is also possible to use the exterior housing of the equipment as a radiator. This makes it all the more necessary to connect the housing to the ground of the system comprising the equipment.

FIG. 1 represents an electrical architecture 10 comprising two static converters, i.e. a rectifier 12 and an inverter 14. The electrical architecture 10 is well-suited to equip a vehicle, in particular an aircraft. The electrical architecture 10 comprises an alternating network 16 which makes it possible to supply to a load 18, such as, for example an engine, via the rectifier 12, generating a direct voltage from the alternating voltage obtained from the alternating network 16, and via the inverter 14, supplying an alternating voltage to the load 18 from the direct voltage.

In FIG. 1, the electrical architecture 10 is represented in a summary way. In practice, the direct voltage can form a network making it possible to supply to a large number of loads, each of which can operate with a different alternating voltage. It is possible to adapt the frequency of the alternating voltage to the needs of the load. For example the speed of the engine can be modulated by varying the frequency by means of the inverter 14. A plurality of inverters can supply to the same load. The electrical architecture 10 can be reconfigured in real time. It makes it possible to supply to a load by means of as many converters as necessary, such as, for example, described in the patent application published under no. EP 2 887 519 and filed in the name of the applicant.

Common mode disturbances can circulate in the electrical architecture 10. These disturbances, which are represented in thick broken lines in FIG. 1, circulate mainly through a ground 20 of the electrical architecture 10. Since the alternating network 16 is connected to the ground 20, the disturbances are superimposed on the alternating voltages of the alternating network 16, then on the direct voltages obtained from the rectifier 12.

Hitherto, the common mode disturbances have been limited by means of inductive filters positioned for example on the direct network. As illustrated in FIG. 1, a common mode filter 22 comprises two inductors positioned on the same magnetic core. A phase of the direct network circulates in each of the inductors. The inductors are produced by means of electrical conductors wound on the common magnetic core. The electrical conductors forming the inductors have dimensions such as to withstand the useful current of the direct network. As a result, the cross-sections of the conductors are large. The magnetic core on which the conductors are wound is also voluminous. This gives rise to a large weight and volume for the filter 22.

In addition, the electronic switches of the converters have a parasitic capacitor 24 formed between the channel for conduction of the switch, the sole plate and the radiator. This capacitor 24 is derived from the proximity between the conduction channel, the sole plate and the radiator, which proximity is necessary for the discharge of the heat released during switching operations.

Internal experimentations have shown that the common mode disturbances tend to be propagated via the parasitic capacitors 24 of the electronic switches in order to reach the ground 20. In FIG. 1, only the parasitic capacitors 24 of the electronic switches of the inverter 14 are represented. The diodes of the rectifier 12 can also have the same type of parasitic capacitor, as soon as one of the electrodes is positioned in the vicinity of, or in contact with, a mechanical part which is connected electrically to the ground 20. The currents which form the common mode disturbances are all the greater, the more the switching frequency increases. With use of electronic switches which can achieve extremely short switching times, the disturbance currents become more and more preoccupying. Because of their volume and mass, the present solutions which make it possible to reduce the disturbances, in particular the common mode currents, are difficult to implement with the new generations of electronic switches.

### SUMMARY OF INVENTION

The invention proposes a solution to these problems by filtering at the source the currents which can pass into the parasitic capacitors of the electronic switches.

For this purpose, the subject of the invention is a component which is configured to switch an electrical signal, the component comprising:
an insulating substrate bearing a semiconductor chip which ensures switching of the signal;
a sole plate on which the substrate is secured, the sole plate being configured to discharge heat emitted during switching of the component;
a conductive plane positioned between the sole plate and the insulating substrate, the conductive plane being insulated electrically against the sole plate;
a specific component with impedance of at least 1 Ohm and/or at least 1 µH, by means of which the conductive plane is connected to a reference voltage.

Advantageously, the component is a resistor of at least 1 Ohm.

The subject of the invention is also a static converter comprising a plurality of components according to one of the preceding claims, wherein the conductive planes and the sole plates of each component are in common.

Advantageously, the converter comprises a first group and a second group of components, in each of the groups of components the conductive planes and the sole plates of each component are in common, the conductive plane of the first group is connected to a first reference voltage by means of a first inductor, and the conductive plane of the second group is connected to a second reference voltage by means of a second inductor, and the two inductors are coupled, and have an impedance of at least 1 µH.

### BRIEF DESCRIPTION OF THE DRAWINGS

The invention will be better understood and other advantages will become apparent from reading the detailed description of an embodiment provided by way of example, which description is illustrated by the appended drawing in which:

FIG. 1, already described, represents an electrical architecture in which the invention can be implemented;

FIG. 2 represents a switching component according to the invention;

FIG. 3 represents a diagram equivalent to the component of FIG. 1;

FIG. 4 represents a plurality of switching components of a static converter according to the invention;

FIG. 5 represents schematically a static converter according to the invention.

For the sake of clarity, the same elements will bear the same references in the different figures.

### DETAILED DESCRIPTION

FIG. 2 represents in cross-section a switching component 30 which implements an active, semiconductor-based chip 32. Any type of switching component can be implemented within the context of the invention. The component can have natural switching such as a diode, or controlled switching such as a thyristor or a transistor. Hitherto, many materials have been used to produce switching components, in particular silicon, germanium, gallium arsenide, silicon carbide, gallium nitride. The invention can be implemented irrespective of the semiconductor material used.

FIG. 2 represents the component 30 schematically in cross-section. The chip 32 is deposited on an insulating substrate 34, which for example is made of ceramic. Metallization covers the substrate 34 selectively, and makes it possible to connect the chip 32 electrically. In this case, the metallization comprises two parts 36 and 38. The part 36 receives a pin 40, and the part 38 receives a pin 42. The part 36 extends below the chip 32, and forms a first electrode of the component 30. The part 38 is connected electrically to the upper part of the chip 32 by means of one or more metal legs 44 forming a second electrode of the component 30. An electrical signal can circulate between the two pins 40 and 42 according to the state of the junction in the semiconductor forming the chip 32. In other words, the component 30 ensures the switching of the electrical signal. For a component with natural switching, the difference of potential between the two pins 40 and 42 determines the state of the junction, and for a component with controlled switching, a control electrode, not represented in FIG. 2, permits triggering of the switching by making the junction go from a blocked state to an active state. The control electrode can be connected to another part of the metallization by means of another leg which is not situated on the cross-sectional plane of FIG. 2.

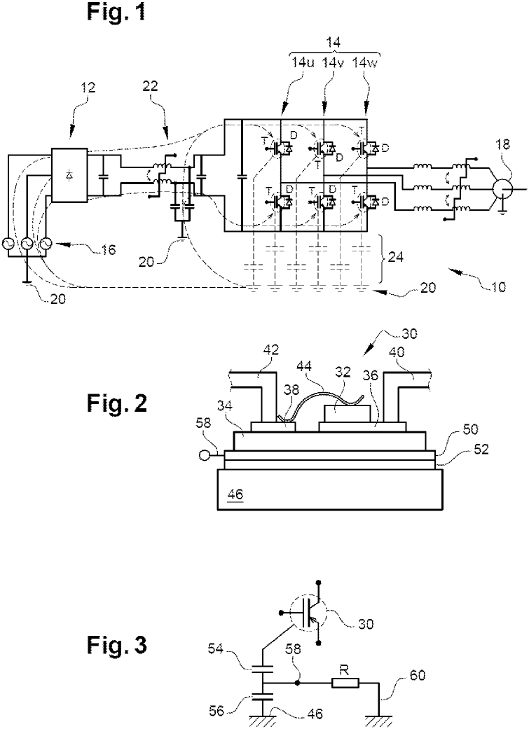

During its operation, the component 30 releases heat forming losses which must be discharged. This heat is mainly released during switching operations, and when the junction is active as a result of its internal resistance. The heat which is generated in the chip 32 is mainly drained towards a sole plate 46 which for example is made of metal alloy, for its good capacity to conduct heat. The sole plate 46 can for example be made of copper alloy or aluminium alloy. The sole plate 46 can be secured on a radiator, not represented in FIG. 1, which permits discharge of the heat. The discharge can take place into the ambient air by natural or forced convection. The discharge can also take place by means of one of the channels which circulate in the radiator, and in which a heat-transfer fluid circulates. The size of the radiator is selected according to the heat generated by the component 30 during use, and, for discharge by convection, according to the ambient medium in which the radiator bathes. It is common to connect the radiator to the ground of the equipment in which the component 30 is used, for example a converter 12 or 14 as represented in FIG. 1.

As described above, a parasitic capacitor is formed between firstly the chip 32 and the parts 36 and 38 of the metallization, and secondly the sole plate 46, with the substrate 34 forming a dielectric of this parasitic capacitor. Another parasitic capacitor is formed in the chip 32 itself, between the electrodes thereof. A displacement current can form between the junction and the sole plate 46, through the parasitic capacitor. This current can be all the greater, the more the speed of switching increases. In practice, during switching, the current which circulates in the junction is established and is interrupted, forming a current step in a time chart. The applicant has noticed that the repetition of these current steps generates significant leakage currents circulating in the ground of the system through the parasitic capacitor of the component 30. The invention seeks to limit the current circulating in this parasitic capacitor by means of a filter placed as close as possible to the chip 32.

According to the invention, a conductive plane 50 is positioned between the sole plate 46 and the insulating substrate 34. The conductive plane 50 is insulated electrically firstly by the chip 32 and the two parts 36 and 38 of the metallization, and secondly by the sole plate 46. On the chip and metallization side, the insulation of the conductive plane 50 is ensured by the substrate 34. On the sole plate 46 side, an insulating film 52 can be interposed between the conductive plane 50 and the sole plate 46. The conductive plane 50 can be a metal film which for example is made of copper alloy or aluminium alloy deposited on the face of the substrate 34 opposite the one which receives the metallization. The conductive plane 50 can be produced from any other type of conductive material, such as, for example, based on carbon. The conductive plane 50 can be continuous or produced in the form of a grid which has openings. The cross-section of the openings is defined according to the wavelength of the parasitic signals which it is wished to filter. It will be appreciated that the insulating film 52 is selected in order to ensure the electrical insulation of the conductive plane 50 relative to the sole plate 46. It is advantageous to select a material which has good thermal conduction properties, in order to avoid restricting the thermal transfer of the calorific energy dissipated by the chip 32 towards the sole plate 46. For this purpose it is possible to select an insulating film 52 based on silicon or mica. The electrical insulation of the conductive plane 50 against the sole plate 46 can also be ensured by means of a layer, for example of the varnish type, deposited on the conductive plane 50 facing the sole plate 46. The level of electrical insulation between the conductive plane 50 and the sole plate 46 is defined according to the difference of potential which can exist between the conductive plane 50 and the sole plate 46. This difference of potential will be specified hereinafter.

FIG. 3 represents in the form of an electronic diagram the switching component and the parasitic capacitors which connect it to the sole plate 46. The component 30 is schematized by a transistor. As previously stated, other switching components can be implemented within the context of the invention. A first capacitor 54 is formed firstly between the chip 32 and its metallization, and secondly the conductive plane 50. The substrate 34 forms the dielectric of the capacitor 54. A second capacitor 56 is formed between the conductive plane 50 and the sole plate 46, which is connected to the potential of a reference voltage such as a ground. The insulating film 52 forms the dielectric of the capacitor 56. In view of the arrangement of the conductive plane 50 between the substrate 34 and the sole plate 46, the two capacitors 54 and 56 can be considered to be connected in series.

The component 30 also comprises an electrical contact 58, which is configured to connect the conductive plane 50 electrically. The connection makes it possible to provide a damping filter with an electronic component which can be on the exterior of the component 30. In the diagram of FIG. 3, the electrical contact 58 appears at the common point of the two capacitors 54 and 56. It is possible for example to connect the conductive plane 50 to a ground terminal of the component 30, by means of a resistor R. The ground terminal 60 can be connected to any reference voltage. By connecting the ground terminal 60 to the potential of the sole plate 46, there is little difference of potential at the terminals of the capacitor 56. It is thus possible to reduce the thickness of the insulation between the conductive plane 50 and the sole plate 46. The conductive plane 50 could be connected directly to a reference voltage. The parasitic capacitors 54, 56 and the connection wires already have resistors, the value of which is typically approximately a few milliohms. When coupled with the capacitor added by the presence of the conductive plane, this low resistance makes it possible at the most to offset the parasitic resonance frequency caused by the parasitic capacitors of the component. The damping is virtually non-existent. During tests carried out internally, the applicant found that resistance of at least one Ohm gave good results for attenuating the amplitude of certain undesirable frequencies. More specifically, in an inverter without the conductive plane, parasitic currents circulating in the ground, and having amplitude spikes around 1 MHz were found. By using a conductive plane associated with a resistance of one Ohm for each switching component of the inverter, the spikes were attenuated by approximately twenty dB.

In addition, by using a specific component in order to provide the resistor R, it is possible to position it at a selected location, in order for the dissipation of the energy of the parasitic current to be able to take place for example on a heat dissipater provided for this purpose. The resistance value of the specific resistive component R of at least one Ohm is added to the resistances of the parasitic capacitors and of the connection wires of the conductive plane 50 in its connection to the reference voltage. As previously stated, the resistance value of the specific resistive component R is approximately 1000 times greater than that of the resistances of the parasitic capacitors and of the connection wires. Consequently, almost all of the energy of the parasitic current is dissipated in the specific component. Other types of passive or even active components can be connected to the electrical contact 58. In particular, it is possible to connect passive components of the capacitor and/or inductor type between the electrical contact 58 and a reference voltage as a complement to, or in the place of, the resistor R. In the case of an inductor, during tests carried out internally, the applicant found that a value of at least 1 µH gave good results for participating in the damping of the parasitic current. In the case of a wound inductor, it is found that its value tends to decrease when the frequency of the current increases, mainly because of the skin effect. The inductance value of 1 µH starting from which the results are sensitive is measured at 10 kHz.

It is also possible to combine a specific resistive component R and a specific inductive component L with the capacitor 56, in order to obtain a damping circuit which makes it possible both to offset the resonance frequency and to damp the harmonics of the parasitic current.

These components can be positioned in the housing of the switching component 30. The electrical contact is then an extension of the conductive plane projecting from the substrate 34. The electrical contact 58 can also be a part of the conductive plane 50. The resistor R, or more generally the component connected to the electrical contact 58, can be fitted on the surface of the substrate 34. Alternatively, the electrical contact 58 can come out of the component, and allow a designer of equipment in which it is possible for example to locate the rectifier 12, the converter 14 and the load 18, to select a component to be connected to the electrical contact 58, which component is suitable for the equipment and the parasitic currents encountered.

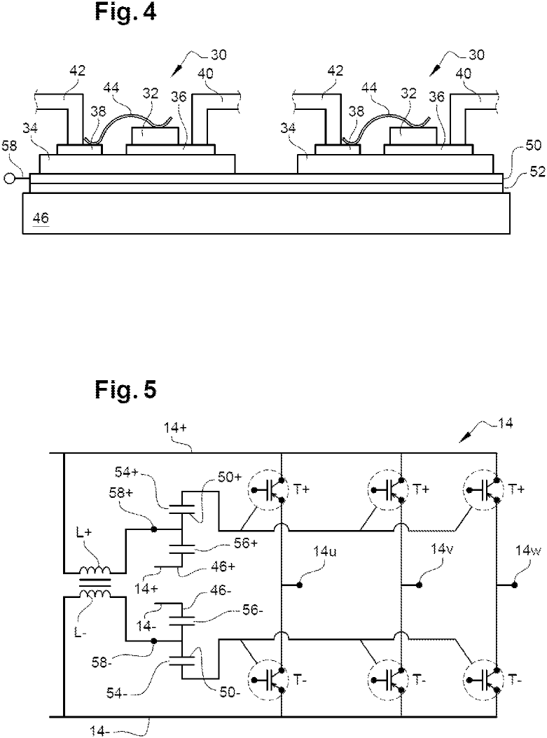

FIG. 4 represents a plurality of switching components which have a sole plate 46 in common. FIG. 5 represents in the form of an electronic diagram a converter 14 of the three-phase inverter type, in which the invention is implemented. As indicated above, the invention can be implemented in any type of converter, irrespective of the number of switching components. FIGS. 4 and 5 relate to converters which implement a plurality of switching components. In these converters, it is advantageous to mutualize the conductive plane, which becomes common to the different switching components, or at least to a group of a plurality of switching components of the converter. FIG. 5 shows an inverter. It will be appreciated that the mutualization of a conductive plane can be applied to any type of converter, for example in a rectifier.

FIG. 4 represents two switching components 30. Unlike the component 30 described in an isolated manner by means of FIG. 2, in FIG. 4 the sole plate 46 and the conductive plane 50 are common to the two switching components 30. In FIG. 4, the insulating film 52 is also common to the two switching components 30. As previously, any other means for insulating the conductive plane 50 against the sole plate 46 remains possible. The electrical contact 58 is associated with the conductive plane 50, and is also common to the two switching components 30.

The inverter 14, represented schematically in FIG. 5, makes it possible to supply three phases 14u, 14v and 14w with alternating voltage from two direct voltages 14+ and 14-. The inverter 14 comprises two groups of switching components. The first group comprises transistors with the references T+, making it possible to switch the direct voltage 14+. Each transistor T+ of the first group contributes to the supply of one of the phases 14u, 14v and 14w. Similarly, the second group comprises transistors with the reference T-, making it possible to switch the direct voltage 14-. Each transistor T- of the second group contributes to the supply of one of the phases 14u, 14v and 14w.

The three transistors T+ of the first group have a common conductive plane 50+, and the transistors T- of the second group have a common conductive plane 50-. The converter 14 can comprise only a single sole plate common to all the transistors T+ and T-. The sole plate is for example connected to a ground of equipment in which the converter 14 is incorporated. Alternatively, it is possible to provide two distinct sole plates 46+ and 46-, one per group of transistors T+ on the one hand and T- on the other hand. The two sole plates 46+ and 46- can be connected to the same reference voltage or to two distinct reference voltages. For example the sole plate 46+ associated with the transistors T+ can be connected to the direct voltage 14+, and the sole plate 46- associated with the transistors T- can be connected to the direct voltage 14-, as illustrated in FIG. 5. It is also possible to connect the sole plate 46+ to the direct voltage 14-, and the sole plate 46- to the direct voltage 14+.

The presence of two conductive planes 50+ and 50- gives rise to the presence of two capacitors, respectively 54+ and 54-, firstly between the transistors T+ and the conductive plane 50+, and secondly between the transistors T- and the conductive plane 50-. Associated with each conductive plane 50+ and 50-, there is an electrical contact 58, respectively 58+ and 58-. FIG. 5 shows two capacitors 56+ and 56- formed between the conductive plane, respectively 50+ and 50- and their corresponding sole plate or the sole plate common to all the transistors T+ and T-.

It is easy to transpose the diagram shown in FIG. 5 to other types of converter, for example to a complete bridge rectifier 12, i.e. comprising four rectifier diodes. It is possible to define there a first group of two diodes switching one of the phases of an alternating voltage, and a second group of two diodes switching the other phase of the alternating voltage. In a rectifier of this type, a first conductive plane can be common to the first group of diodes, and a second conductive plane can be common to the second group of diodes.

It has been seen by means of FIG. 3 that the conductive plane could be connected to a reference voltage by means of any type of active or passive component. The reference voltage can for example be the ground 60 of the equipment in which the inverter 14 is implemented. The reference voltage can also be one of the direct voltages 14+ or 14-. It is also possible to dissociate the reference voltage. More specifically, the electrical contact 58+ can be connected, directly or by means of components of the type R, L, C, to the direct voltage 14+. In addition, the electrical contact 58- can be connected, directly or by means of components of the type R, L, C, to the direct voltage 14-. In the inverter 14, the conductive plane 50+ is connected to a reference voltage by means of an inductor L+, and the conductive plane 50- is connected to the same reference voltage 60 by means of an inductor L-. In FIG. 5, the two inductors L+ and L- have a common point which is connected to the same reference voltage. Alternatively, it is possible to dissociate the reference voltages to which the two inductors L+ and L- are connected. For example, the inductor L+ can be connected to the direct voltage 14+, and the inductor L- can be connected to the direct voltage 14-.

The two inductors L+ and L- can be coupled for example by winding them onto the same magnetic core. As a complement to the two inductors L+ and L-, it is possible to add other active or passive components. As described above, it is possible to connect between the common point of the two inductors, or between each inductor and the respective reference voltage, passive components of the resistor and/or capacitor and/or inductor type.

The use of two inductors coupled in common mode can be implemented for any other type of converter, and in particular for the rectifier 12.

1. A component which is configured to switch an electrical signal, the component comprising:
an insulating substrate bearing a semiconductor chip which ensures switching of the signal;
a sole plate on which the substrate is secured, the sole plate being configured to discharge heat emitted during switching of the component;
a conductive plane positioned between the sole plate and the insulating substrate, the conductive plane being insulated electrically against the sole plate;
a specific component with impedance of at least 1 Ohm and/or at least 1 µH, by means of which the conductive plane is connected to a reference voltage.

2. The component according to claim 1, wherein the specific component is a resistor of at least 1 Ohm.

3. A static converter comprising a plurality of components according to claim 1, wherein the conductive planes and the sole plates of each component are in common.

4. A static converter comprising a plurality of components according to claim 1, wherein the conductive planes and the sole plates of each component are in common, further comprising a first group of components and a second group of components, wherein, in each of the groups of components the conductive planes and the sole plates of each component are in common, wherein the conductive plane of the first group is connected to a first reference voltage by means of a first inductor, and the conductive plane of the second group is connected to a second reference voltage by means of a second inductor, and wherein the two inductors are coupled, and have an impedance of at least 1 µH.
